(19) United States
(12) Patent Application Publication
(10) Pub. No.: US 2016/0260704 A1
(43) Pub. Date: Sep. 8, 2016

(54) High Voltage Device with a Parallel Resistor

(71) Applicant: Taiwan Semiconductor Manufacturing Company, Ltd., Hsin-Chu (TW)

(72) Inventors: Ker-Hsiao Huo, Hsin-Chu (TW); Hsin-Chih Chiang, Hsin-Chu (TW); Kevin Chen, Hsin-Chu (TW); Chun Lin Tsai, Hsin-Chu (TW); Yi-Min Chen, Hsin-Chu (TW)

(21) Appl. No.: 14/638,407

(22) Filed: Mar. 4, 2015

(51) Int. Cl. H01L 27/06; H01L 29/78; H01L 29/08; H01L 29/10; H01L 21/768; H01L 29/423; H01L 21/8234; H01L 29/66; H01L 21/762; H01L 49/02; H01L 29/06

(52) U.S. Cl. CPC H01L 27/0629; H01L 28/20; H01L 29/7816; H01L 29/0865; H01L 29/0882; H01L 29/1095; H01L 29/0653; H01L 29/42356; H01L 21/8234; H01L 29/66681; H01L 21/76202; H01L 21/768

(57) ABSTRACT

A high voltage semiconductor device includes: a source having a first conductivity type and a drain having the first conductivity type disposed in a substrate; a first dielectric component disposed on a surface of the substrate between the source and the drain; a drift region disposed in the substrate, wherein the drift region has the first conductivity type; a first doped region having a second conductivity type and disposed within the drift region under the dielectric component, the second conductivity type being opposite the first conductivity type; a second doped region having the second conductivity type and disposed within the drift region, wherein the second doped region at least partially surrounds one of the source and the drain; a resistor disposed directly on the dielectric component; and a gate disposed directly on the dielectric component, wherein the gate is electrically coupled to the resistor.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometry size (i.e., the smallest component that can be created using a fabrication process) has decreased.

These ICs include high voltage semiconductor devices. As geometry size continues to be scaled down, it has become increasingly more difficult for existing high voltage semiconductor devices to achieve certain performance criteria. As an example, a breakdown voltage may become a performance limitation for traditional high voltage semiconductor devices. In conventional high voltage semiconductor devices, improvement in the breakdown voltage by reducing drift region doping may lead to an undesirable increase in an on-state resistance of the device.

Therefore, while existing high voltage semiconductor devices have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart illustrating a method for fabricating a high voltage semiconductor device according to various aspects of the present disclosure.

FIGS. 2-5 are diagrammatic fragmentary cross-sectional side views of various embodiments of a high voltage semiconductor device in accordance with various aspects of the present disclosure.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for the sake of simplicity and clarity.

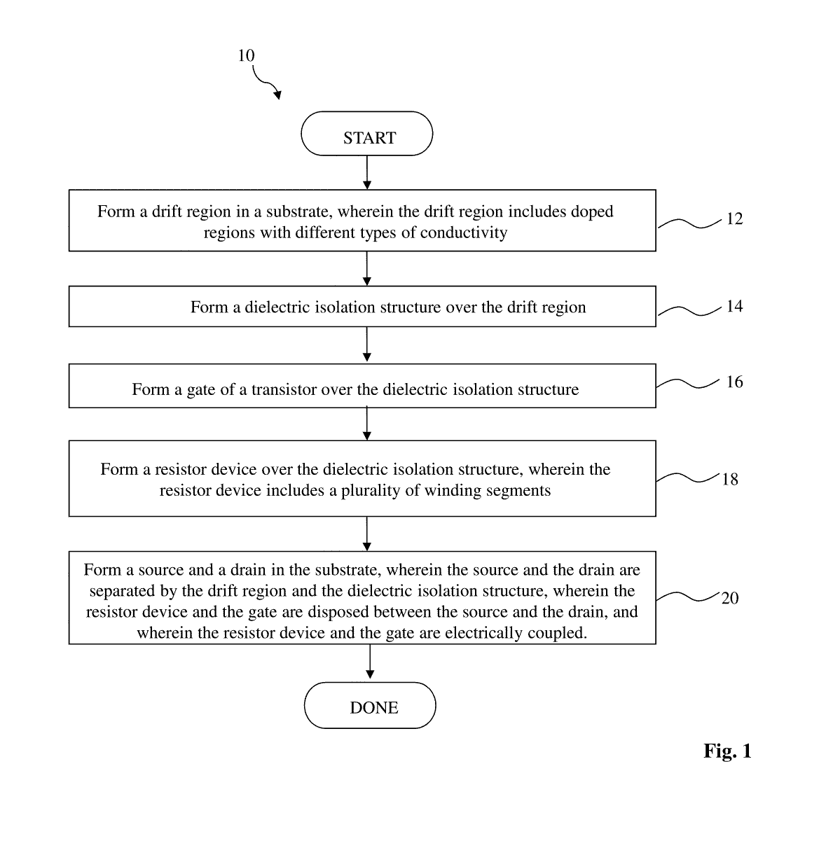

Illustrated in FIG. 1 is a flowchart of a method 10 of fabricating a high voltage semiconductor device according to various aspects of the present disclosure. The method 10 starts with operation 12 in which a drift region is formed in a substrate. The drift region includes doped regions with different types of conductivity. The method 10 then continues to operation 14 in which a dielectric isolation structure is formed over the drift region. In some embodiments, the dielectric isolation structure includes a local oxidation of silicon (LOCOS) that protrudes out of a surface of the substrate. The method 10 further continues to operation 16 in which a gate of a transistor is formed over a portion of the dielectric isolation structure. After the gate is formed, the method 10 continues to operation 18 in which a resistor device is formed over the dielectric isolation structure. The resistor device includes a plurality of winding segments. In some embodiments, the winding segments have substantially uniform dimensions and spacing. Subsequently, the method 10 ends in operation 20 in which a source and a drain are formed in the substrate. More specifically, the source and the drain are separated by the drift region and the dielectric isolation structure, and the resistor device and the gate are disposed between the source and the drain. In accordance with some illustrative embodiments, the resistor device and the gate are electrically coupled.

By electrically coupling the gate and the resistor device, the resistor device formed over the drift region may be applied with a same voltage level as the gate of the transistor. As such, an inversion layer is formed at the interface between the drift region and the dielectric isolation structure when a voltage is applied to the gate. Here, as one example, inversion is generally meant that, in a semiconductor structure that has a first type of conductivity, an opposite type of conductivity is induced, in part, in the semiconductor structure. In an example of the high voltage semiconductor device described herein, the drift region may have a P-type doped portion and an N-type doped inversion layer is formed at the interface between the drift region and the dielectric isolation structure when a voltage is applied to the gate. In another example, the drift region may have an N-type doped portion and a P-type doped inversion layer is formed at the interface between the drift region and the dielectric isolation structure when a voltage is applied to the gate.

Generally, a lower doping concentration may be used in a drift region of a high voltage device so as to sustain the high voltage device with a higher breakdown voltage. However, lowering the doping concentration results in a less conductive transistor, i.e., a higher conductive resistance, or simply ON resistance. Such increased ON resistance may in turn affect the transistor's performance disadvantageously as a whole, such as lower speed, higher impedance, etc. Without making a compromise of the performance, the device described herein with an induced inversion layer advantageously provides a route for a high voltage device to have a desirable level of a breakdown voltage (high) and a conductive resistance (low) respectively at the same time.

It is understood that additional steps may be performed to complete the fabrication of the high voltage semiconductor device. For example, the method may include a step in which an interconnect structure is formed over the substrate. The interconnect structure either electrically couples the resistor device in parallel to the transistor, or leaves the resistor electrically floating.

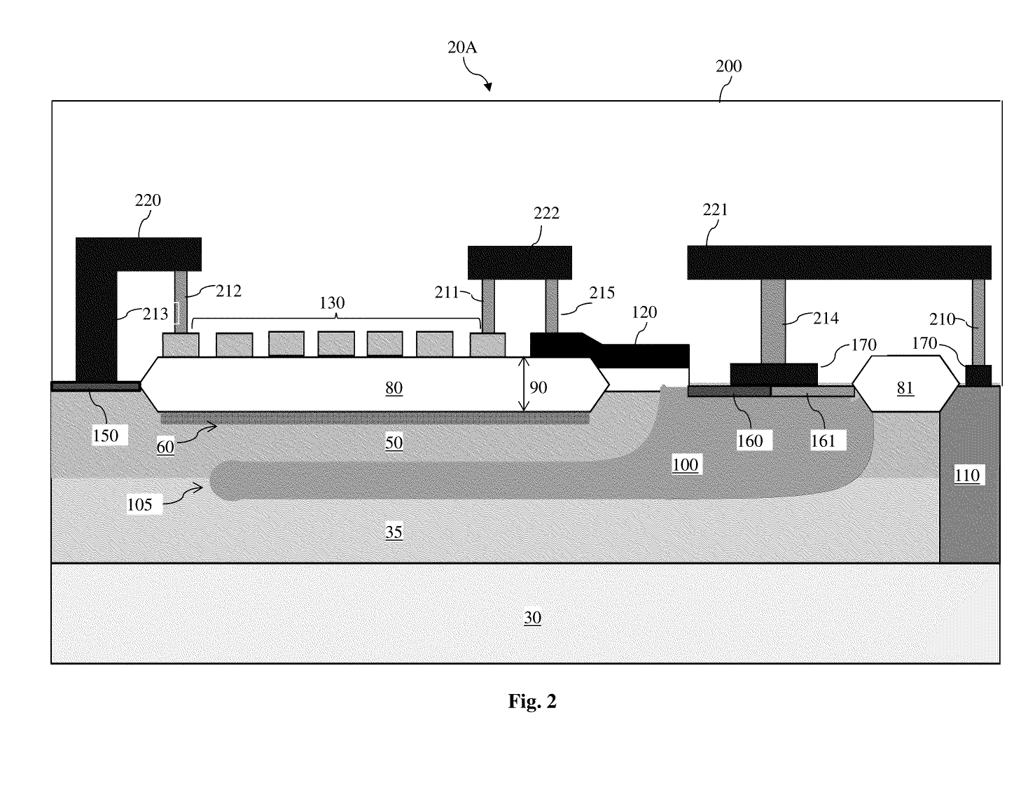

FIG. 2 illustrates a diagrammatic fragmentary cross-sectional side view of a high voltage semiconductor device 20A according to an embodiment of the present disclosure. It is understood that FIG. 2 has been simplified for a better understanding of the inventive concepts of the present disclosure.

Referring to FIG. 2, the high voltage semiconductor device 20A includes a portion of a substrate 30. The substrate 30 is doped with a P-type dopant such as boron. In another embodiment, the substrate 30 may be doped with an N-type dopant such as phosphorous or arsenic. The substrate 30 may also include other suitable elementary semiconductor materials, such as diamond or germanium; a suitable compound semiconductor, such as silicon carbide, indium arsenide, or indium phosphide; or a suitable alloy semiconductor, such as silicon germanium carbide, gallium arsenic phosphide, or gallium indium phosphide.

A buried well 35 is formed in a portion of the substrate 30 through an ion implantation process. The buried well 35 is formed of an opposite type of conductivity than that of the substrate 30. In the illustrated embodiment, the buried well 35 is N-type doped, since the substrate 30 herein is a P-type substrate. In another embodiment where the substrate 30 is an N-type substrate, the buried well 35 is P-type doped. The buried well 35 is formed by an implantation process having a dose that is in a range from about 1×10¹² atoms/centimeter² to about 2×10¹² atoms/centimeter². The buried well 35 has a doping concentration that is in a range from about 1×10¹⁵ atoms/centimeter³ to about 1×10¹⁶ atoms/centimeter³.

A high voltage doped well 50 is formed in the substrate 30. The high voltage doped well 50 is formed by an ion implantation process. For example, the doped well 50 is formed by an implantation process having a dose that is in a range from about 3×10¹² atoms/centimeter² to about 4×10¹² atoms/centimeter². In an embodiment, the high voltage doped well has a doping concentration that is in a range from about 1×10¹⁵ atoms/centimeter³ to about 1×10¹⁶ atoms/centimeter³. A patterned photoresist layer (not illustrated) may be formed over the substrate 35 as a mask during the implantation process.

The high voltage doped well 50 is doped with the same type of conductivity as the buried well 35 (i.e., opposite from that of the substrate 30). Thus, the high voltage doped well 50 is a high voltage N-well (HVNW) in the illustrated embodiment. The high voltage doped well 50 may also be referred to as a drift region 50.

A plurality of isolation structures are formed over the drift region 50, for example isolation structures 80 and 81 shown in FIG. 2. The isolation structures 80-81 may include a dielectric material. In the embodiment shown in FIG. 2, the isolation structures 80-81 are Local Oxidation of Silicon (LOCOS) devices (also referred to as field oxide). The LOCOS devices may be formed using a nitride mask and thermal-growing an oxide material through the mask openings. At least a portion of the LOCOS devices protrude downwardly into, and protrude upwardly out of, the drift region 50. Furthermore, the LOCOS devices may have uneven thicknesses (or depths). For example, the edge portions of the LOCOS devices may have tapered shapes and thus smaller thicknesses. In some embodiments, the non-edge portions of the LOCOS devices have a thickness 90, which may be in a range from about 0.2 microns (um) to about 1 um in certain embodiments.

Alternatively, the isolation structures 80-81 may include shallow trench isolation (STI) devices or deep trench isolation (DTI) devices. The dielectric structures 80-81 help define boundaries of certain doped regions to be formed later, for example boundaries of source and drain regions of a Field Effect Transistor (FET) device.

A doped extension region 100 is formed in the drift region 50. In the embodiment shown, the doped extension region 100 is formed between the high voltage doped well 50 and the buried well 35. The doped extension region 100 has the same type of conductivity as the substrate 30 but an opposite type of conductivity as the drift region 50. Thus, in the embodiment shown, the doped extension region 100 has a P-type of conductivity.

In certain embodiments, the doped extension region 100 may be formed by two separate ion implantation processes. The first ion implantation process forms a doped region at least partially in the upper portion of the drift region 50 (near the upper surface of the drift region 50). The second ion implantation process forms a deeper and wider doped region that “extends” or “protrudes” laterally outward. Subsequently, a thermal process may be performed to inter-diffuse and merge the two doped regions into a single doped region, thereby forming the doped extension region 100. As a result, the doped extension region 100 has a protruding portion 105 (or protruding tip) that laterally extends or protrudes partially into the drift region 50. Therefore, the doped extension region 100 may also be referred to as a P-body extension region 100 herein.

As is shown in FIG. 2, the protruding portion 105 is buried inside the drift region 50, rather than being located near the upper surface of the drift region 50. In other words, the protruding portion 105 is located away from the surface of the drift region 50. One benefit offered by the protruding portion 105 is that it can provide extra conduction path to reduce an on-state resistance of a transistor.

In one embodiment, using the same implantation processes that form the doped extension region 100, a doped isolation region 110 is also formed. In an embodiment, the doped isolation region 110 is formed using the second ion implantation process (the one that forms the wider and deeper doped region). To define the lateral size of the doped isolation region 110, a patterned photoresist mask layer may be formed that has an opening, and the above-mentioned second ion implantation process may be performed through the opening to define the doped isolation region 110. Stated differently, the doped isolation region 110 is also formed during the formation of the protruding portion 105 of the doped extension region 100. Thus, the doped isolation region 110 may have a dopant concentration level that is approximately the same as the dopant concentration level of the protruding portion 105.

A gate 120 is formed over the drift region 50. Specifically, the gate 120 may be formed on a portion of the isolation structure 80. The gate 120 may be formed by a plurality of deposition and patterning processes. In some embodiments, the gate 120 includes a polysilicon material having a silicided surface. The silicided surface may include tungsten silicide, for example.

A resistor device 130 is formed over the isolation structure 80. In some embodiments, the resistor device 130 includes a polysilicon material, and may therefore be referred to as a polysilicon resistor. For example, the resistor device 130 may include an undoped polysilicon material, a P-doped polysilicon material, or a silicide on polysilicon material. The resistor device 130 is designed to handle high voltages, for example voltages greater than about 100 volts, and may be as high as a few hundred volts. Thus, the resistor device 130 may also be referred to as a high voltage resistor device. In some embodiments, the resistor device 130 is formed at the same time as the gate 120. In other embodiments, the resistor device 130 and the gate 120 are formed at separate times using different processes.

According to the various aspects of the present disclosure, the resistor device 130 has an elongate and winding shape. In the cross-sectional view shown in FIG. 2, the resistor device 130 appears as a plurality of winding segments. Although the winding segments of the resistor device 130 appear to separately distributed in such a cross-sectional view, it is understood that these winding segments may actually be parts of an individual elongate resistor device 130. In some embodiments, the winding segments of the resistor device 130 have substantially uniform vertical and lateral dimensions (i.e., heights/thicknesses and widths). For example, each winding segment's vertical and lateral dimensions may vary within a few percentage points (or less than a percentage point) of those of another winding segment. In some embodiments, the spacing between adjacent winding segments of the resistor device 130 is also substantially uniform. In some alternative embodiments, the spacing between adjacent winding segments of the resistor device 130 may be varying in a suitable application.

A heavily doped drain region 150 is formed at the upper surface of the drift region 50 on one side of the isolation structure 80, and a heavily doped source region 160 is formed at the upper surface of the doped extension region 100 on the opposite side of the isolation structure 80. In other words, the drain region 150 and the source region 160 are located on opposite sides of the isolation structure 80. A heavily doped region 161 is also formed adjacent to the source region 160. In some embodiments, the heavily doped region 161 may serve as a guard ring.

The drain region 150 and the source region 160 have the same type of conductivity as the drift region 50, and the heavily doped region 161 has the same type of conductivity as the doped extension region 100. Thus, in the embodiment shown in FIG. 2, the drain region 150 the source region 160 are N-type doped, and the heavily doped region 161 is P-type doped. The drain region 150 and the source region 160 have dopant concentration levels that are significantly higher than the dopant concentration level of the drift region 50. The heavily doped region 161 has a dopant concentration level that is significantly higher than the dopant concentration level of the doped extension region 100. Therefore, in the embodiment shown, the drain region 150 and the source region 160 may be referred to as N+ regions, and the heavily doped region 161 may be referred to as an P+ region. Conductive pads such as pads 170 may also be formed on the source or drain regions and the doped isolation region 110 to help establish electrical connections to these source and drain regions.

The gate 120 (which is located between the drain region 150 and the source region 160), the drain region 150, and the source region 160 are components of a field-effect transistor (FET) device. The FET device is a high voltage transistor configured to handle high voltages in the present disclosure. For example, the FET device is configured to operate under voltages as high as a few hundred volts.

An interconnect structure 200 is formed over the surface of the substrate 30. In other words, the interconnect structure 200 is formed over the isolation structures 80-81, the gate 120, the resistor device 130, and the source and drain regions 160 and 150, among other things. The interconnect structure 200 includes a plurality of patterned dielectric layers and conductive layers that provide interconnections (e.g., wiring) between circuitries, inputs/outputs, and various doped features (for example, the drift region 50). In more detail, the interconnect structure 200 may include a plurality of interconnect layers, also referred to as metal layers. Each of the interconnect layers includes a plurality of interconnect features, also referred to as metal lines. The metal lines may be aluminum interconnect lines or copper interconnect lines, and may include conductive materials such as aluminum, copper, aluminum alloy, copper alloy, aluminum/silicon/copper alloy, titanium, titanium nitride, tantalum, tantalum nitride, tungsten, polysilicon, metal silicide, or combinations thereof. The metal lines may be formed by a process including physical vapor deposition (PVD), chemical vapor deposition (CVD), sputtering, plating, or combinations thereof.

The interconnect structure 200 includes an interlayer dielectric (ILD) that provides isolation between the interconnect layers. The ILD may include a dielectric material such as a low-k material or an oxide material. The interconnect structure 200 also includes a plurality of contacts/contacts that provide electrical connections between the different interconnect layers and/or the features on the substrate, such as the source and drain regions 160 and 150 or the resistor device 130.

For example, as part of the interconnect structure 200, multiple contacts 210-215 are formed to provide electrical connections to the doped isolation region 110, the gate 120, the resistor device 130, the drain region 150, and the source region 160. In the embodiment shown in FIG. 2, the contacts 211-212 are formed on, and electrically coupled to, opposite distal ends of the resistor device 130.

The interconnect structure 200 also includes metal lines (or interconnect lines) that are electrically coupled to the contacts 210-215. For example, a metal line 220 is electrically coupled to the contacts 212 and 213, a metal line 221 is electrically coupled to the contacts 210 and 214, and a metal line 222 is electrically coupled to the contacts 211 and 215. In other words, one end of the resistor device 130 is electrically coupled to the drain region 150, and the other end of the resistor device 130 is electrically coupled to the gate 120. In this manner, the resistor device 130 is electrically coupled to the FET device in parallel, specifically, to the drain and gate of the FET device in parallel. As such, the resistor device 130 is applied with a same voltage level as the gate so that an inversion layer 60 is formed at the interface between drift region 50 and isolation structure 80 when a high gate voltage is applied. The formation of the inversion layer 60 causes the transistor to be more conductive while simultaneously sustaining the breakdown voltage of the transistor at a desirably high value.

Further, according to the various aspects of the present disclosure, the parallel-coupled resistor device 130 improves the uniformity of the electric field in the drift region 50. As discussed above, the resistor device 130 has a plurality of substantially uniform winding segments, whose spacing there between is also substantially uniform. As such, each winding segment can bear a substantially fixed and uniform amount of electrical voltage. In other words, when a high electrical voltage (for example on the order of a few hundred volts) is applied to the FET between its source and drain, that high electrical voltage is applied to the resistor device 130 as well, since it is electrically coupled in parallel to the FET transistor. The uniformity in the dimensions and spacing of the resistor device 130 segments allows the high electrical voltage to be spread evenly and uniformly across the span of the resistor device 130, thereby improving the uniformity of the electric field in the drift region 50 below the resistor device 130. As a result of the more uniformly distributed electric field, the breakdown voltage of the FET transistor is increased as well. It has been observed during testing that by implementing the parallel resistor device according to the present disclosure, the breakdown voltage can be increased by over a hundred volts.

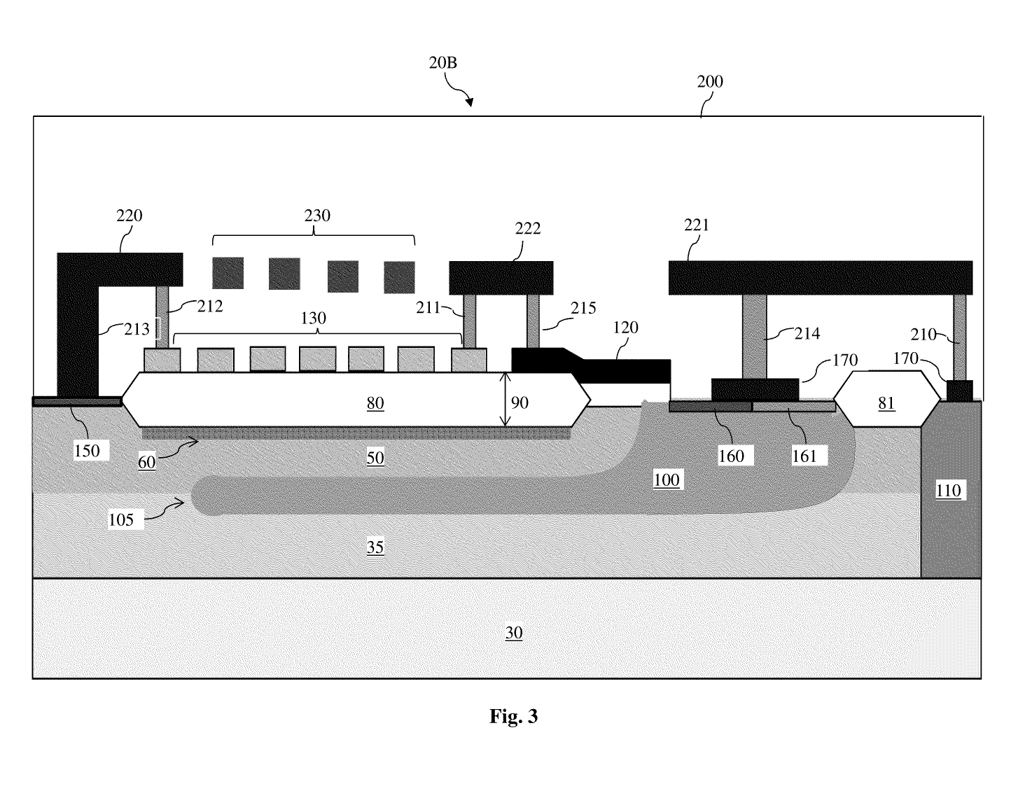

FIGS. 3-5 illustrate diagrammatic fragmentary cross-sectional side views of a high voltage semiconductor device according to alternative embodiments of the present disclosure. For reasons of consistency and clarity, similar components are labeled the same throughout FIGS. 2-5.

Referring to FIG. 3, a high voltage semiconductor device 20B is similar to the high voltage semiconductor device 20A in many regards. One difference between the high voltage semiconductor device 20A and 20B is that the high voltage semiconductor device 20B includes an electrically floating metal conductor 230 as part of interconnect structure 200. The electrically-floating metal conductor 230 is disposed over the resistor device 130, but it has no direct electrical connections to components of the FET transistor.

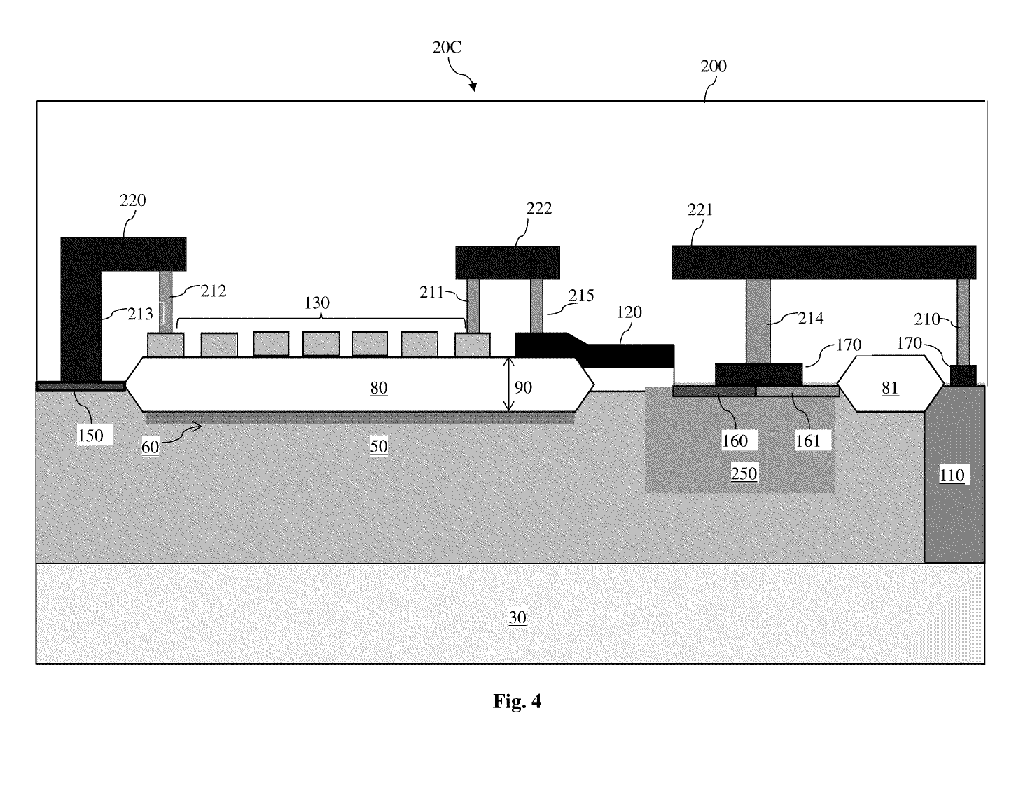

Referring now to FIG. 4, a high voltage semiconductor device 20C is similar to the high voltage semiconductor device 20A in many regards. One difference between the high voltage semiconductor device 20A and 20C is that the high voltage semiconductor device 20G includes a drift region 50 having one type of conductivity that extends to substrate 30. In the embodiment illustrated, the high voltage semiconductor device 20C has an N-type drift region. In comparison, the drift region 50 of the high voltage semiconductor device 20A includes both N-type doped portions (for example the buried N-well 35 and the HVNW 50) and a P-type doped portion (for example the P-body extension 100). The source region 160 of the FET transistor device is formed within (or is surrounded by) a doped well 250, which in the embodiment illustrated in a P-well. In an embodiment, the doped well 250 is formed in the drift region 50. The doped well 250 has the same type of conductivity as the substrate 30 but an opposite type of conductivity as the drift region 50. Thus, in the embodiment shown, the doped well 250 100 has a P-type of conductivity.

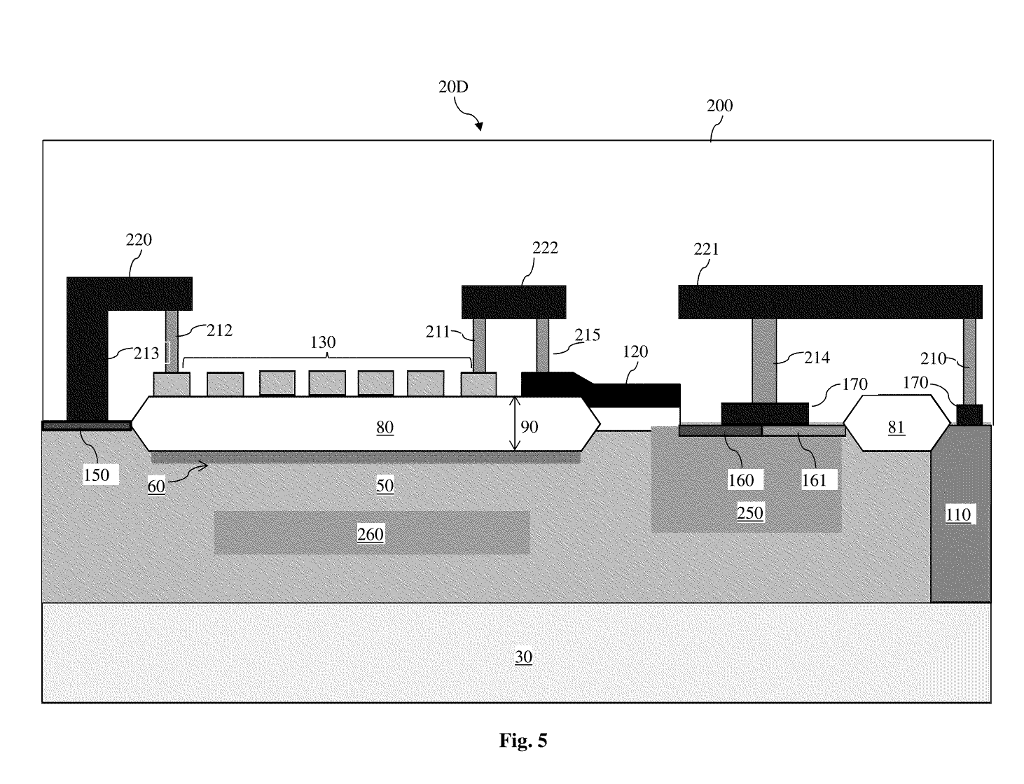

Referring now to FIG. 5, a high voltage semiconductor device 20D is similar to the high voltage semiconductor device 20C of FIG. 4 in many regards. One difference is that the high voltage semiconductor device 20D further includes a doped buried layer 260 in the drift region 50. The doped buried layer 260 has the opposite type of conductivity than that of the drift region 50. Therefore, the doped buried layer 260 is a P-buried layer in the embodiment shown in FIG. 5. Functionally, the doped buried layer 260 is similar to the P-body extension 100 discussed above. However, as shown, doped buried layer 260 is discontinuous from doped well 250.

It is understood that the aspects of each of the embodiments of the high voltage semiconductor device 20A-20D may be combined with one another depending on design needs and manufacturing requirements. For example, it is understood that an embodiment of the high voltage semiconductor device may have an electrically-floating resistor device (such as in the embodiment shown in FIG. 3) and a drift region having a single type of conductivity (such as in the embodiment shown in FIG. 4). For reasons of simplicity, each possible combination of the above embodiments is not specifically discussed herein.

Additional processing steps may be performed to complete the fabrication of the high voltage semiconductor device. For example, after the interconnect structure is formed, a passivation process may be performed to the high voltage semiconductor device. As another example, the high voltage semiconductor device may also include one or more testing processes such as wafer acceptance testing processes. For reasons of simplicity, these additional fabrication processes are not discussed in detail herein.

One of the broader forms of the present disclosure involves a device that includes: a source having a first conductivity type and a drain having the first conductivity type disposed in a substrate; a first dielectric component disposed on a surface of the substrate between the source and the drain; a drift region disposed in the substrate, wherein the drift region has the first conductivity type; a first doped region having a second conductivity type and disposed within the drift region under the dielectric component, the second conductivity type being opposite the first conductivity type; a second doped region having the second conductivity type and disposed within the drift region, wherein the second doped region at least partially surrounds one of the source and the drain; a resistor disposed directly on the dielectric component; and a gate disposed directly on the dielectric component, wherein the gate is electrically coupled to the resistor.

Another one of the broader forms of the present disclosure involves a semiconductor device that includes: a transistor having a gate, a source, and a drain, wherein: the source and the drain are formed in a doped substrate and are separated by a drift region of the substrate; the gate is formed over the drift region and between the source and the drain; and the transistor is configured to handle high voltage conditions that are at least a few hundred volts; a dielectric structure formed between the source and the drain of the transistor, the dielectric structure protruding into and out of the substrate, wherein different parts of the dielectric structure have uneven thicknesses; and a resistor formed over the dielectric structure, the resistor having a plurality of winding segments that are substantially evenly spaced apart. In accordance with various embodiments, the resistor is electrically coupled to the gate of the transistor.

One more of the broader forms of the present disclosure involves a method of fabricating a high voltage semiconductor device. The method includes: forming a drift region in a substrate, wherein the drift region includes doped regions with different types of conductivity, forming a dielectric isolation structure over the drift region, forming a gate of a transistor over the dielectric isolation structure, forming a resistor device over the dielectric isolation structure, wherein the resistor device includes a plurality of winding segments, and forming a source and a drain in the substrate, wherein the source and the drain are separated by the drift region and the dielectric isolation structure, wherein the resistor device and the gate are disposed between the source and the drain, and wherein the resistor device and the gate are electrically coupled.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A device comprising:
a source having a first conductivity type and a drain having the first conductivity type disposed in a substrate;
a first dielectric component disposed on a surface of the substrate between the source and the drain;
a drift region disposed in the substrate, wherein the drift region has the first conductivity type;
a first doped region having a second conductivity type and disposed within the drift region under the dielectric component, the second conductivity type being opposite the first conductivity type;
a second doped region having the second conductivity type and disposed within the drift region, wherein the second doped region at least partially surrounds one of the source and the drain;
a resistor disposed directly on the dielectric component; and
a gate disposed directly on the dielectric component, wherein the gate is electrically coupled to the resistor.

2. The device of claim 1, wherein the first doped region and the second doped region intersect one another to form a continuous doped extension region.

3. The device of claim 1, wherein the first doped region is discontinuous from the second doped region such that a portion of the drift region extends between the first and second doped regions.

4. The device of claim 1, further comprising a second dielectric component disposed with the substrate and interfaces with the second doped region.

5. The device of claim 4, further comprising a doped isolation region having the second conductivity disposed in the substrate and interfaces with the second dielectric component.

6. The device of claim 1, wherein the drift region includes an inversion layer having the second conductivity type when voltage is applied at the gate.

7. The device of claim 6, wherein the inversion is positioned at an interface between the first dielectric component and the drift region.

8. The device of claim 1, wherein the resistor is electrically floating.

9. A device comprising:
a transistor having a gate, a source, and a drain, wherein:
the source and the drain are formed in a doped substrate and are separated by a drift region of the substrate, wherein the drift region includes both P-doped and N-doped portions;
the gate is formed over the drift region and between the source and the drain; and
the transistor is configured to handle high voltage conditions that are at least a few hundred volts;
a dielectric structure formed between the source and the drain of the transistor, the dielectric structure protruding into and out of the substrate, wherein different parts of the dielectric structure have uneven thicknesses; and
a resistor formed over the dielectric structure, the resistor having a plurality of winding segments that are substantially evenly spaced apart;
wherein the resistor is electrically coupled to the gate of the transistor.

10. The semiconductor device of claim 9, wherein the transistor is configured to operate in an inversion mode when voltage is applied at the gate.

11. The semiconductor device of claim 9, wherein:
the P-doped portion includes a P-body extension that is electrically coupled to the source and protrudes laterally under the dielectric structure; and
the N-doped portion includes an n-well that is located between the dielectric structure and the P-body extension.

12. The semiconductor device of claim 9, wherein the resistor is electrically floating.

13. The semiconductor device of claim 9, wherein the resistor is electrically coupled to the transistor in parallel.

14. The semiconductor device of claim 13, wherein the resistor is electrically coupled in parallel to the drain and the gate.

15. The semiconductor device of claim 9, wherein the winding segments of the resistor have substantially uniform lateral dimensions.

16. The semiconductor device of claim 9, wherein:
the resistor contains polysilicon; and
the dielectric structure includes field oxide.

17-20. (canceled)

21. A semiconductor device comprising:
a substrate;
a drift region in the substrate, wherein the drift region includes doped regions with different types of conductivity;
a dielectric isolation structure over the drift region;
a gate of a transistor over the dielectric isolation structure;
a resistor device over the dielectric isolation structure, wherein the resistor device includes a plurality of winding segments;
a doped region in the substrate, wherein the doped region includes a first portion positioned adjacent to the gate, and an extension portion positioned under the isolation structure; and
a source and drain in the substrate;
wherein the resistor device and the gate are electrically coupled.

22. The device of claim 21, further comprising:
an interconnect structure over the substrate in a manner such that the resistor device is either electrically coupled in parallel to the transistor or electrically floating.

23. The device of claim 21, wherein the plurality of winding segments of the resistor device have substantially uniform dimensions and spacing.

24. The device of claim 21, wherein the dielectric isolation structure includes a local oxidation of silicon (LOCOS) that protrudes out of a surface of the substrate.
